(19) United States
(12) Patent Application Publication
(10) Pub. No.: US 2024/0105465 A1
(43) Pub. Date: Mar. 28, 2024

(54) METHOD OF PROCESSING SUBSTRATE, METHOD OF MANUFACTURING SEMICONDUCTOR DEVICE, RECORDING MEDIUM, AND SUBSTRATE PROCESSING APPARATUS

(71) Applicant: Kokusai Electric Corporation, Tokyo (JP)

(72) Inventors: Takahiro MIYAKURA, Toyama-shi (JP); Akito Hirano, Toyama-shi (JP); Yasunobu Koshi, Toyama-shi (JP); Yasuhiro Megawa, Toyama-shi (JP)

(73) Assignee: Kokusai Electric Corporation, Tokyo (JP)

(21) Appl. No.: 18/472,815

(22) Filed: Sep. 22, 2023

(30) Foreign Application Priority Data
Sep. 26, 2022 (JP) 2022-152822

(51) Int. Cl. H01L 21/3205; C23C 16/52; H01L 21/3215

(52) U.S. Cl. CPC H01L 21/32055; C23C 16/52; H01L 21/32155

(57) ABSTRACT

There is provided a technique that includes: (a) supplying a first gas containing a Group 14 element to a substrate including a recess; (b) supplying a second gas containing a Group 15 or Group 13 element to the substrate; (c) forming a first film containing the Group 14 element in the recess by performing (a) and (b) with the second gas at a first concentration, and stopping film formation before the recess is filled up with the first film; and (d) after (c), performing (b) with the second gas at a second concentration and heat-treating the substrate.

### CROSS-REFERENCE TO RELATED APPLICATION

This application is based upon and claims the benefit of priority from Japanese Patent Application No. 2022-152822, filed on Sep. 26, 2022, the entire contents of which are incorporated herein by reference.

### TECHNICAL FIELD

The present disclosure relates to a method of processing a substrate, a method of manufacturing a semiconductor device, a recording medium, and a substrate processing apparatus.

### BACKGROUND

In the related art, as a process of manufacturing a semiconductor device, a process of forming a film on a substrate is sometimes performed.

### SUMMARY

Some embodiments of the present disclosure provide a technique capable of improving a quality of a film formed on a substrate.

According to some embodiment of the present disclosure, there is provided a technique that includes: (a) supplying a first gas containing a Group 14 element to a substrate including a recess; (b) supplying a second gas containing a Group 15 or Group 13 element to the substrate; (c) forming a first film containing the Group 14 element in the recess by performing (a) and (b) with the second gas at a first concentration, and stopping film formation before the recess is filled up with the first film; and (d) after (c), performing (b) with the second gas at a second concentration and heat-treating the substrate.

### BRIEF DESCRIPTION OF DRAWINGS

The accompanying drawings, which are incorporated in and constitute a part of the specification, illustrate embodiments of the present disclosure.

FIG. 1 is a schematic configuration diagram of a vertical process furnace of a substrate processing apparatus suitably used in embodiments of the present disclosure, in which the portion of the process furnace is illustrated in a vertical and cross-sectional view.

FIG. 2 is a schematic configuration diagram of a vertical process furnace of the substrate processing apparatus suitably used in embodiments of the present disclosure, in which a portion of the process furnace is illustrated in a cross-sectional view taken along line A-A in FIG. 1.

FIG. 3 is a schematic configuration diagram of a controller of a substrate processing apparatus suitably used in embodiments of the present disclosure, in which a control system of the controller is illustrated in a block diagram.

FIG. 4 is a diagram showing an example of a flowchart of a substrate processing process according to a first embodiment of the present disclosure.

FIGS. 5A to 5D are schematic cross-sectional views of a wafer including a recess (trench or blind hole) according to the first embodiment of the present disclosure. FIG. 5A is a schematic cross-sectional view showing a surface of the wafer after a seed layer is formed. FIG. 5B is a schematic cross-sectional view showing a surface of the wafer after film formation. FIG. 5C is a schematic cross-sectional view showing a surface of the wafer during heat treatment. FIG. 5D is a schematic cross-sectional view showing a surface of the wafer after heat treatment.

FIG. 6 is a diagram showing an example of a flowchart of a substrate processing process according to a second embodiment of the present disclosure.

FIGS. 7A to 7E are schematic and cross-sectional views of a wafer including a recess according to a second embodiment of the present disclosure. FIG. 7A is a schematic and cross-sectional view showing a surface of the wafer after a seed layer is formed. FIG. 7B is a schematic and cross-sectional view showing a surface of the wafer after film formation. FIG. 7C is a schematic and cross-sectional view showing a surface of the wafer after seeding. FIG. 7D is a schematic and cross-sectional view showing a surface of the wafer during heat treatment. FIG. 7E is a schematic cross-sectional view showing a surface of the wafer after heat treatment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to unnecessarily obscure aspects of the various embodiments.

### First Embodiment of the Present Disclosure

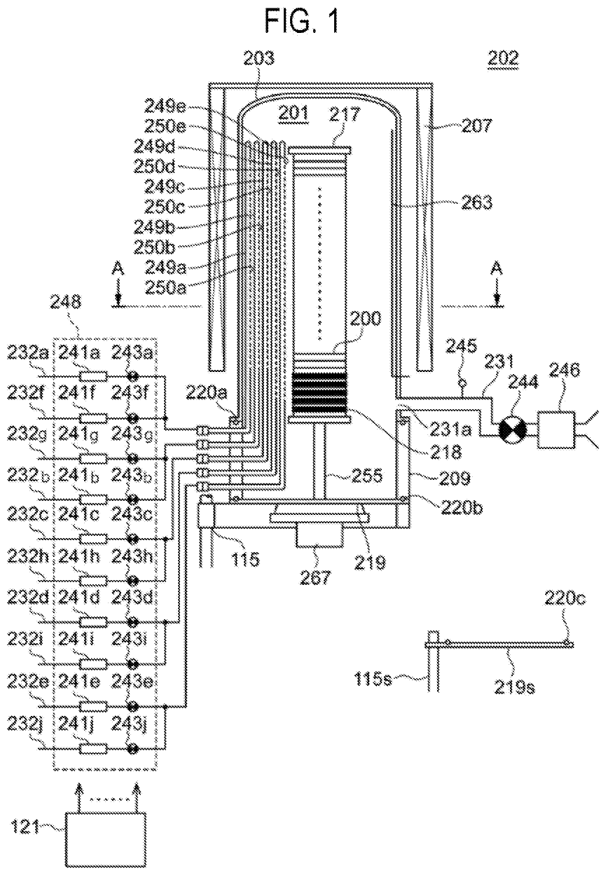

Hereinafter, the first embodiment of the present disclosure will be described mainly with reference to FIGS. 1 to 4 and 5A to 5D. The drawings used in the following description are schematic, and dimensional relationships of the respective components, ratios of the respective components, and the like shown in the drawings may not match actual ones. Further, dimensional relationships of the respective components, ratios of the respective components, and the like may not match one another among a plurality of drawings.

### (1) Configuration of Substrate Processing Apparatus

As shown in FIG. 1, a process furnace 202 includes a heater 207 as a heating equipment (temperature regulator). The heater 207 is formed in a cylindrical shape and is vertically installed by being supported by a holding plate. The heater 207 also functions as an activator (exciter) configured to activate (excite) a gas with heat.

Inside the heater 207, a reaction tube 203 is arranged concentrically with the heater 207. The reaction tube 203 is made of, for example, a heat-resistant material such as quartz (SiO₂) or silicon carbide (SiC) and is formed in a cylindrical shape with an upper end thereof closed and a lower end thereof opened. Below the reaction tube 203, a manifold 209 is arranged concentrically with the reaction tube 203. The manifold 209 is made of, for example, a metallic material such as stainless steel (SUS) or the like and is formed in a cylindrical shape with upper and lower ends thereof opened. The upper end of the manifold 209 is engaged with the lower end of the reaction tube 203 and is configured to support the reaction tube 203. An O-ring 220a as a seal is provided between the manifold 209 and the reaction tube 203. The reaction tube 203 is installed vertically like the heater 207. A process container (reaction container) mainly includes the reaction tube 203 and the manifold 209. A process chamber 201 is formed in a hollow area of the process container. The process chamber 201 is configured to be capable of accommodating wafers 200 as substrates. The wafers 200 are processed in the process chamber 201.

In the process chamber 201, nozzles 249a to 249e as first to fifth suppliers are provided so as to penetrate a side wall of the manifold 209. Gas supply pipes 232a to 232e are connected to the nozzles 249a to 249e, respectively. The nozzles 249a to 249e are different nozzles, and each of the nozzles 249b and 249d is installed adjacent to the nozzle 249c. Each of the nozzles 249a and 249e is provided adjacent to an opposite side from a side on which the nozzle 249b and the nozzle 249d are adjacent to the nozzle 249c.

At the gas supply pipes 232a to 232e, mass flow controllers (MFC) 241a to 241e as flow rate controllers (flow rate control parts) and valves 243a to 243e as opening/closing valves are respectively installed in the named order from the upstream side of a gas flow. Gas supply pipes 232f to 232j are connected to the gas supply pipes 232a to 232e on the downstream side of the valves 243a to 243e, respectively. At the gas supply pipes 232f to 232j, MFCs 241f to 241j and valves 243f to 243j are respectively installed in the named order from the upstream side of a gas flow. The gas supply pipes 232a to 232e are made of, for example, a metallic material such as stainless steel (SUS) or the like.

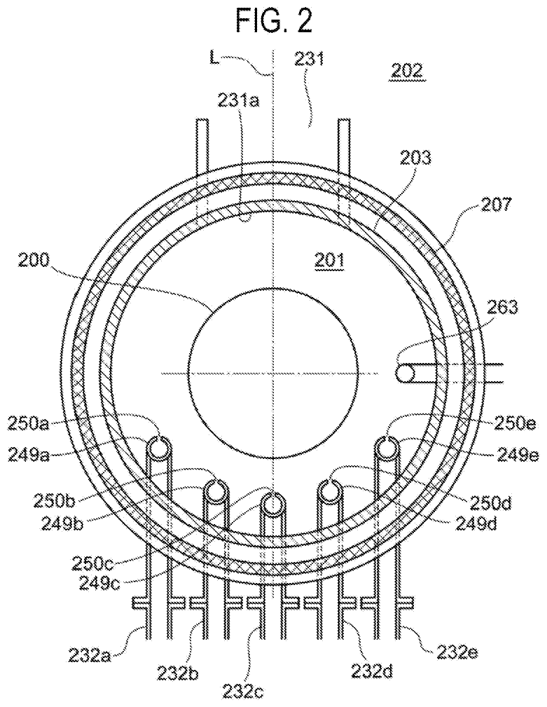

As shown in FIG. 2, the nozzles 249a to 249e are respectively arranged in a space formed in an annular shape in a plane view between the inner wall of the reaction tube 203 and the wafers 200 and are installed to extend upward in an arrangement direction of the wafers 200 from a lower side to an upper side of the inner wall of the reaction tube 203. In other words, the nozzles 249a to 249e are respectively installed in a region horizontally surrounding a wafer arrangement region, in which the wafers 200 are arranged, on a lateral side of the wafer arrangement region so as to extend along the wafer arrangement region. In a plane view, the nozzle 249c is arranged so as to face the below-described exhaust port 231a on a straight line across centers of the wafers 200 loaded into the process chamber 201. The nozzles 249b and 249d are arranged so as to sandwich a straight line L passing through the nozzle 249c and a center of the exhaust port 231a from both sides along the inner wall of the reaction tube 203 (outer peripheral portions of the wafers 200). Further, the nozzles 249a and 249e are respectively arranged on the opposite side from the side on which the nozzles 249b and 249d are adjacent to the nozzle 249c, so as to sandwich the straight line L from both sides along the inner wall of the reaction tube 203. The straight line L is also a straight line passing through the nozzle 249c and the centers of the wafers 200. That is, it may be said that the nozzle 249d is installed opposite the nozzle 249b with the straight line L interposed therebetween. Further, it may be said that the nozzle 249e is installed opposite the nozzle 249a with the straight line L interposed therebetween. The nozzles 249b and 249d are arranged in a line-symmetric relationship with the straight line L as an axis of symmetry. Further, the nozzles 249a and 249e are arranged in a line-symmetric relationship with the straight line L as an axis of symmetry. Gas supply holes 250a to 250e configured to supply gases are formed on the side surfaces of the nozzles 249a to 249e, respectively. The gas supply holes 250a to 250e are respectively opened to face the exhaust port 231a in a plane view and may supply gases toward the wafers 200. The gas supply holes 250a to 250e are formed from the lower side to the upper side of the reaction tube 203.

A first gas containing a Group 14 element or a third gas containing a Group 14 element is supplied from the gas supply pipe 232a into the process chamber 201 via the MFC 241a, the valve 243a and the nozzle 249a.

A second gas containing a Group 15 or Group 13 element is supplied from the gas supply pipe 232b into the process chamber 201 via the MFC 241b, the valve 243b, and the nozzle 249b.

A hydrogen (H)-containing gas is supplied from the gas supply pipe 232c into the process chamber 201 via the MFC 241c, the valve 243c, and the nozzle 249c.

A fourth gas containing a Group 14 element is supplied from the gas supply pipe 232d into the process chamber 201 via the MFC 241d, the valve 243d, and the nozzle 249d.

The fourth gas containing a Group 14 element is supplied from the gas supply pipe 232e into the process chamber 201 via the MFC 241e, the valve 243e, and the nozzle 249e.

An inert gas is supplied into the process chamber 201 from the gas supply pipes 232f to 232j via the MFCs 241f to 241j, the valves 243f to 243j, the gas supply pipes 232a to 232e, and the nozzles 249a to 249e, respectively. The inert gas acts as a purge gas, a carrier gas, a dilution gas, and the like.

The inert gas is supplied into the process chamber 201 from the gas supply pipes 232f to 232j via the MFCs 241f to 241j, the valves 243f to 243j, the gas supply pipes 232a to 232e, and the nozzles 249a to 249e, respectively. The inert gas acts as a purge gas, a carrier gas, a dilution gas, and the like.

A first gas supply system or a third gas supply system mainly includes the gas supply pipe 232a, the MFC 241a, and the valve 243a. A second gas supply system mainly includes the gas supply pipe 232b, the MFC 241b, and the valve 243b. A H-containing gas supply system mainly includes the gas supply pipe 232c, the MFC 241c, and the valve 243c. A fourth gas supply system mainly includes the gas supply pipes 232d and 232e, the MFCs 241d and 241e, and the valves 243d and 243e. An inert gas supply system mainly includes the gas supply pipes 232f to 232j, the MFCs 241f to 241j, and the valves 243f to 243j. The gas supply pipe 232f, the MFC 241f, and the valve 243f may be included in the first gas supply system or the third gas supply system. The gas supply pipe 232g, the MFC 241g, and the valve 243g may be included in the second gas supply system. The gas supply pipe 232h, the MFC 241h, and the valve 243h may be included in the H-containing gas supply system. The gas supply pipes 232i and 232j, the MFCs 241i and 241j, and the valves 243i and 243j may be included in the fourth gas supply system.

Any one or the entirety of the various supply systems described above may be configured as an integrated supply system 248 in which the valves 243a to 243j, the MFCs 241a to 241j, and the like are integrated. The integrated supply system 248 is connected to each of the gas supply pipes 232a to 232j, and is configured such that the operation of supplying various gases into the gas supply pipes 232a to 232j, i.e., the opening/closing operations of the valves 243a to 243j, the flow rate regulation operations by the MFCs 241a to 241j, and the like are controlled by a controller 121, which will be described later. The integrated supply system 248 is configured as an integral or divided integrated unit, and is configured such that the integrated supply system 248 may be attached or detached to or from the gas supply pipes 232a to 232j, and the like on an integrated unit basis, and maintenance, replacement, expansion, and the like of the integrated supply system 248 may be performed on an integrated unit basis.

An exhaust port 231a configured to exhaust an atmosphere in the process chamber 201 is provided at the lower side of the side wall of the reaction tube 203. As shown in FIG. 2, the exhaust port 231a is provided at a position facing the nozzles 249a to 249e (gas supply holes 250a to 250e) with the wafers 200 interposed therebetween in a plane view. The exhaust port 231a may be provided to extend from the lower side to the upper side of the side wall of the reaction tube 203, i.e., along the wafer arrangement region. An exhaust pipe 231 is connected to the exhaust port 231a. A vacuum pump 246 as an vacuum exhauster is connected to the exhaust pipe 231 via a pressure sensor 245 as a pressure detector (pressure detection part) configured to detect the pressure inside the process chamber 201 and a APC (Auto Pressure Controller) valve 244 as a pressure regulator (pressure regulation part). The APC valve 244 is configured such that it may perform or stop vacuum evacuation of the interior of the process chamber 201 by being opened and closed in a state in which the vacuum pump 246 is operated. Furthermore, the APC valve 244 is configured such that it may regulate the pressure inside the process chamber 201 by adjusting a valve opening state based on the pressure information detected by the pressure sensor 245 in a state in which the vacuum pump 246 is operated. An exhaust system mainly includes the exhaust pipe 231, the APC valve 244, and the pressure sensor 245. The vacuum pump 246 may be included in the exhaust system.

A seal cap 219 as a furnace opening lid capable of airtightly closing the lower end opening of the manifold 209 is installed below the manifold 209. The seal cap 219 is made of, for example, a metallic material such as stainless steel (SUS) or the like, and is formed in a disc shape. On an upper surface of the seal cap 219, there is installed an O-ring 220b as a seal which comes into contact with the lower end of the manifold 209. Below the seal cap 219, there is installed a rotator 267 configured to rotate a boat 217 to be described later. A rotating shaft 255 of the rotator 267 is made of, for example, a metallic material such as a stainless steel or the like, and is connected to the boat 217 through the seal cap 219. The rotator 267 is configured to rotate the wafers 200 by rotating the boat 217. The seal cap 219 is configured to be raised or lowered in the vertical direction by a boat elevator 115 as an elevator installed outside the reaction tube 203. The boat elevator 115 is configured as a transfer apparatus (transfer equipment) configured to load or unload (transfer) the wafers 200 into or out of the process chamber 201 by raising or lowering the seal cap 219. The transfer apparatus functions as a provider configured to provide the wafers 200 into the process chamber 201.

Below the manifold 209, a shutter 219s is installed as a furnace opening lid capable of airtightly closing the lower end opening of the manifold 209 in a state in which the seal cap 219 is lowered and the boat 217 is unloaded from the process chamber 201. The shutter 219s is made of, for example, a metallic material such as stainless steel (SUS) or the like and is formed in a disk shape. An O-ring 220c as a seal which comes into contact with the lower end of the manifold 209 is installed on the upper surface of the shutter 219s. The opening/closing operations (elevating operation, rotating operation, and the like) of the shutter 219s are controlled by a shutter opening/closing equipment 115s.

A boat 217 serving as a substrate support is configured to support a plurality of wafers 200, for example, 25 to 200 wafers 200, in such a state that the wafers 200 are arranged in a horizontal posture and in multiple stages along a vertical direction with the centers of the wafers 200 aligned with one another. That is, the boat 217 is configured to arrange the wafers 200 to be spaced apart from each other in a direction perpendicular to the surfaces of the wafers 200. The boat 217 is made of, for example, a heat-resistant material such as quartz or SiC. Heat insulating plates 218 made of, for example, a heat-resistant material such as quartz or SiC, are supported in multiple stages at the bottom of the boat 217.

Inside the reaction tube 203, there is installed a temperature sensor 263 as a temperature detector. By regulating a state of supplying electric power to the heater 207 based on the temperature information detected by the temperature sensor 263, a temperature distribution inside the process chamber 201 becomes a desired temperature distribution. The temperature sensor 263 is installed along the inner wall of the reaction tube 203.

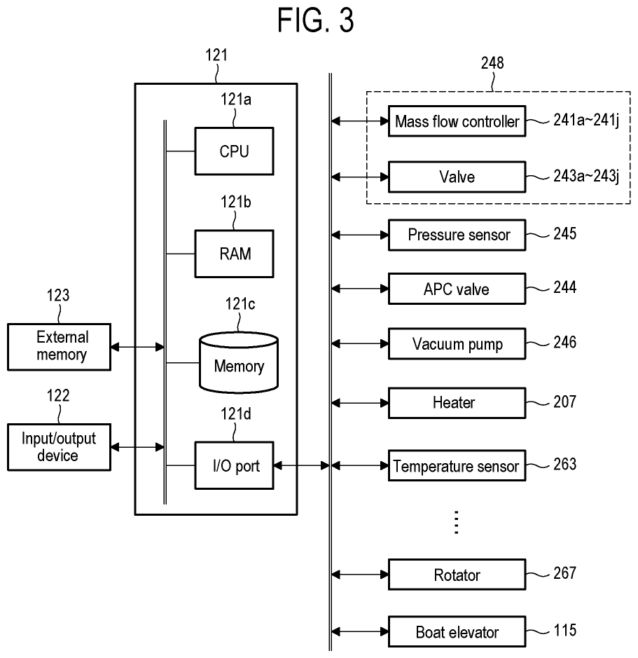

As shown in FIG. 3, the controller 121 as a control part (control means or unit) is configured as a computer including a CPU (Central Processing Unit) 121a, a RAM (Random Access Memory) 121b, a memory 121c, and an I/O port 121d. The RAM 121b, the memory 121c, and the I/O port 121d are configured to be capable of exchanging data with the CPU 121a via an internal bus 121e. An input/output device 122 configured as, for example, a touch panel or the like is connected to the controller 121. In addition, an external memory 123 may be connected to the controller 121.

The memory 121c includes, for example, a flash memory, a HDD (Hard Disk Drive), a SSD (Solid State Drive), or the like. In the memory 121c, there are readably recorded and stored a control program that controls the operation of the substrate processing apparatus, a process recipe in which procedures and conditions of substrate processing to be described later are written, and the like. The process recipe is a combination that causes, by the controller 121, the substrate processing apparatus to execute the respective procedures in a below-described substrate processing process so as to obtain a predetermined result. The process recipe functions as a program. Hereinafter, the process recipe, the control program and the like are collectively and simply referred to as a program. Furthermore, the process recipe is also simply referred to as a recipe. When the term “program” is used herein, it may mean a case of including the recipe, a case of including the control program, or a case of including both the recipe and the control program. The RAM 121b is configured as a memory area (work area) in which programs, data, and the like read by the CPU 121a are temporarily held.

The I/O port 121d is connected to the MFCs 241a to 241j, the valves 243a to 243j, the pressure sensor 245, the APC valve 244, the vacuum pump 246, the temperature sensor 263, the heater 207, the rotator 267, the boat elevator 115, the shutter opening/closing equipment 115s, and the like.

The CPU 121a is configured to be capable of reading and executing the control program from the memory 121c and reading the recipe from the memory 121c in response to an input of an operation command from the input/output device 122 or the like. The CPU 121a is configured to be capable of, according to the contents of the recipe thus read, controlling the flow rate regulation operation for various substances (various gases) by the MFCs 241a to 241g, the opening/closing operations of the valves 243a to 243g, the opening/closing operation of the APC valve 244, the pressure regulation operation by the APC valve 244 based on the pressure sensor 245, the start and stop of the vacuum pump 246, the temperature regulation operation of the heater 207 based on the temperature sensor 263, the rotation and the rotation speed adjustment operation of the boat 217 by the rotator 267, the elevation operation of the boat 217 by the boat elevator 115, the opening/closing operation of the shutter 219s by the shutter opening/closing equipment 115s, and the like.

The controller 121 may be configured by installing, in the computer, the above-described program recorded and stored in an external memory 123. The external memory 123 includes, for example, a magnetic disk such as a HDD or the like, an optical disc such as a CD or the like, a magneto-optical disc such as a MO or the like, a semiconductor memory such as a USB memory, a SSD, or the like, and so forth. The memory 121c and the external memory 123 are configured as a computer readable recording medium. Hereinafter, the memory 121c and the external memory 123 are collectively and simply referred to as a recording medium. As used herein, the term “recording medium” may include the memory 121c, the external memory 123, or both. The program may be provided to the computer using a communication means or unit such as the Internet or a dedicated line using the external memory 123.

### (2) Substrate Processing Process

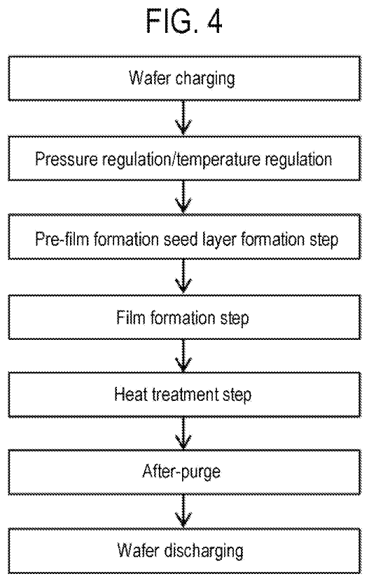

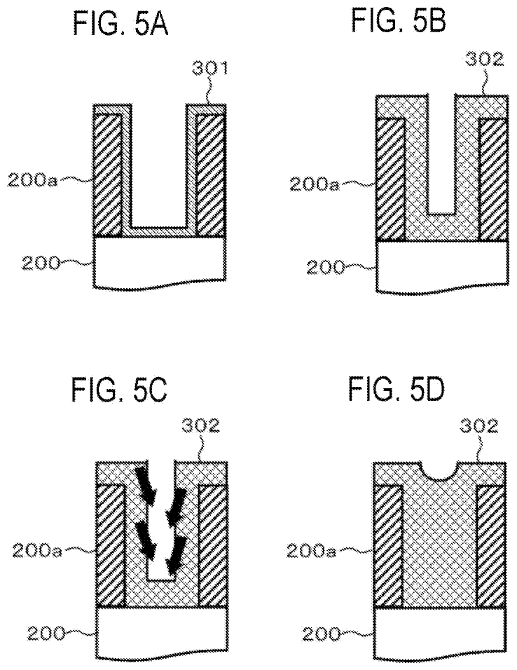

As a process of manufacturing a semiconductor device, an example of a processing sequence of forming a film on a wafer 200 as a substrate by using the above-described substrate processing apparatus will be described mainly with reference to FIGS. 4 and 5A to 5D. In the following description, an operation of each component of the substrate processing apparatus is controlled by the controller 121.

As the wafer 200, for example, a Si substrate made of monocrystalline silicon (Si) or a substrate on which a monocrystalline Si film is formed may be used. As shown in FIG. 5A, a recess is formed on the surface of the wafer 200. A bottom of the recess is made of, for example, monocrystalline Si, and sides and a top of the recess are made of an insulating film 200a such as a silicon nitride film (SiN film) or the like. On the surface of the wafer 200, the monocrystalline Si and the insulating film 200a are exposed.

A processing sequence according to the embodiments of the present disclosure, includes:
(a) a step of supplying a first gas containing a Group 14 element to a wafer 200 including a recess;
(b) a step of supplying a second gas containing a Group 15 or Group 13 element to the wafer 200;
(c) step of forming a first film containing the Group 14 element in the recess by performing (a) and (b) with the second gas at a first concentration, and stopping film formation before the recess is filled up with the first film (film formation step); and
(d) a step of after (c), performing (b) with the second gas at a second concentration and heat-treating the wafer 200 (heat treatment step).

In the following, as an example, a case where the first gas and the second gas are simultaneously supplied in the film formation step will be described.

In the present disclosure, the above-described processing sequence may be denoted as follows for the sake of convenience. The same notation may be used in the following description of modifications, other embodiments, and the like.

first gas+second gas→second gas+heat treatment

In addition, as shown in FIG. 4, the processing sequence according to the embodiments of the present disclosure further includes a pre-film formation seed layer formation step of forming a seed layer on the wafer 200 by supplying a fourth gas containing a Group 14 element to the wafer 200 before performing the film formation step.

In the present disclosure, the above-described processing sequence may be denoted as follows for the sake of convenience. The same notation may be used in the following description of modifications, other embodiments, and the like.

fourth gas first gas+second gas→second gas+heat treatment

The term “wafer” used herein may refer to “a wafer itself” or “a stacked body of a wafer and a predetermined layer or film formed on a surface of the wafer.” The phrase “a surface of a wafer” used herein may refer to “a surface of a wafer itself” or “a surface of a predetermined layer or the like formed on a wafer.” The expression “a predetermined layer is formed on a wafer” used herein may mean that “a predetermined layer is directly formed on a surface of a wafer” or that “a predetermined layer is formed on a layer or the like formed on a wafer.” The term “substrate” used herein may be synonymous with the term “wafer.”

As used herein, the term “layer” includes at least one selected from the group of a continuous layer and a discontinuous layer.

### (Wafer Charging and Boat Loading)

After a plurality of wafers 200 is charged to the boat 217 (wafer charging), the shutter 219s is moved by the shutter opening/closing equipment 115s to open the lower end opening of the manifold 209 (shutter opening). Thereafter, as shown in FIG. 1, the boat 217 supporting the plurality of wafers 200 is lifted by the boat elevator 115 and loaded into the process chamber 201 (boat loading). In such a state, the seal cap 219 seals the lower end of the manifold 209 via the O-ring 220b. Thus, the wafer 200 is prepared in the process chamber 201.

### (Pressure Regulation and Temperature Regulation)

After the boat loading is completed, the inside of the process chamber 201, i.e., the space where the wafer 200 exists, is vacuum-exhausted (decompression-exhausted) by the vacuum pump 246 such that the pressure inside the process chamber 201 becomes a desired pressure (state of vacuum). At this time, the pressure inside the process chamber 201 is measured by the pressure sensor 245, and the APC valve 244 is feedback-controlled based on the measured pressure information. Further, the wafer 200 in the process chamber 201 is heated by the heater 207 such that the wafer 200 reaches a desired processing temperature. At this time, a state of supplying electric power to the heater 207 is feedback-controlled based on the temperature information detected by the temperature sensor 263 such that a temperature distribution inside the process chamber 201 becomes a desired temperature distribution. Further, the rotation of the wafer 200 by the rotator 267 is started. The exhaust of the inside of the process chamber 201 and the heating and rotation of the wafer 200 are continuously performed at least until the processing on the wafer 200 is completed.

### (Pre-Film Formation Seed Layer Formation Step)

Thereafter, a fourth gas containing a Group 14 element is supplied to the wafer 200. This step is performed, for example, by using two kinds of gases among the fourth gases containing Si as a Group 14 element. In the following, a description will be made on an example where one of the two kinds of gases is a halosilane-based gas containing Si and halogen, the other of the two kinds of gases is a silane-based gas containing Si, and a seed layer 301 is formed by performing, a predetermined number of times (n times, where n is an integer of 1 or 2 or more), a cycle including a halosilane-based gas supply step and a silane-based gas supply step. In the present disclosure, a formation sequence of the seed layer 301 may be denoted as follows for the sake of convenience.

(halosilane-based gas→silane-based gas)×n

### [Halosilane-Based Gas Supply Step]

In this step, the halosilane-based gas is supplied to the wafer 200.

Specifically, the valve 243d is opened to allow the halosilane-based gas to flow through the gas supply pipe 232d. A flow rate of the halosilane-based gas is regulated by the MFC 241d. The halosilane-based gas is supplied into the process chamber 201 via the gas supply pipe 232d and the nozzle 249d, and is exhausted from the exhaust port 231a. At this time, the halosilane-based gas is supplied to the wafer 200 from the lateral side of the wafer 200 (halosilane-based gas supply). At this time, the valves 243f to 243j may be opened to supply an inert gas into the process chamber 201 via the nozzles 249a to 249e, respectively.

By supplying the halosilane-based gas to the wafer 200 under a processing condition described later, a native oxide film and impurities may be removed from the surface of the wafer 200 by treatment action (etching action) of the halosilane-based gas, thereby cleaning the surface of the wafer 200.

A processing condition in this step is exemplified as follows:
Processing temperature: 250 to 450 degrees C., specifically 300 to 400 degrees C.
Processing pressure: 400 to 1000 Pa
Supply flow rate of halosilane-based gas: 0.1 to 1 slm
Supply flow rate of inert gas (for each gas supply pipe): 0 to 5 slm
Supply time of each gas: 0.5 to 10 minutes.

In the present disclosure, the expression of a numerical range such as “250 to 450 degrees C.” means that a lower limit and an upper limit thereof are included in the range. Therefore, for example, “250 to 450 degrees C.” means “250 degrees C. or more and 450 degrees C. or less.” The same applies to other numerical ranges. Further, the processing temperature in the present disclosure means the temperature of the wafer 200 or the temperature inside the process chamber 201, and the processing pressure means the pressure inside the process chamber 201. Moreover, the processing time means the time during which the processing is continued. In addition, when 0 slm is included in the supply flow rate, 0 slm means a case where the substance (gas) is not supplied. These also hold true in the following description.

After the surface of the wafer 200 is cleaned, the valve 243d is closed to stop the supply of the halosilane-based gas into the process chamber 201. Then, the inside of the process chamber 201 is vacuum-exhausted to remove gaseous substances and the like remaining in the process chamber 201 from the process chamber 201. At this time, the valves 243f to 243j are opened to supply the inert gas into the process chamber 201 via the nozzles 249a to 249e. The inert gas supplied from the nozzles 249a to 249e acts as a purge gas, such that the inside of the process chamber 201 is purged (purging).

A processing condition when performing purging in this step is exemplified as follows:
Processing temperature: room temperature (25 degrees C.) to 600 degrees C.
Processing pressure: 1 to 30 Pa
Supply flow rate of inert gas (for each gas supply pipe): 0.5 to 20 slm
Supply time of inert gas: 1 to 120 seconds, specifically 1 to 60 seconds.

As the halosilane-based gas, it may be possible to use, for example, a chlorosilane-based gas such as a dichlorosilane (SiH₂Cl₂, abbreviation: DCS) gas, a monochlorosilane (SiH₃Cl, abbreviation: MCS) gas, a tetrachlorosilane (SiCl₄, abbreviation: STC) gas, a trichlorosilane (SiHCl₃, abbreviation: TCS) gas, a hexachlorodisilane (Si₂Cl₆, abbreviation: HCDS) gas, an octachlorotrisilane (Si₃Cl₈, abbreviation: OCTS) gas, or the like. Further, as the halosilane-based gas, it may be possible to use, for example, a tetrafluorosilane (SiF₄) gas, a tetrabromosilane (SiBr₄) gas, a tetraiodosilane (SiI₄) gas, or the like. Thus, as the halosilane-based gas, it may be possible to use, for example, a halosilane-based gas such as a fluorosilane-based gas, a bromosilane-based gas, or an iodosilane-based gas, in addition to the chlorosilane-based gas. One or more selected from the group of these gases may be used as the halosilane-based gas.

As the inert gas, a nitrogen (N₂) gas and a rare gas such as an argon (Ar) gas, a helium (He) gas, a neon (Ne) gas or a xenon (Xe) gas may be used. One or more selected from the group of these gases may be used as the inert gas. This point holds true in each step described later.

### [Silane-Based Gas Supply Step]

After the halosilane-based gas supply step is finished, the silane-based gas is supplied to the wafer 200 in the process chamber 201, i.e., the cleaned surface of the wafer 200.

Specifically, the valve 243e is opened to allow the silane-based gas to flow through the gas supply pipe 232e. A flow rate of the silane-based gas is regulated by the MFC 241e. The silane-based gas is supplied into the process chamber 201 via the nozzle 249e, and is exhausted from the exhaust port 231a. At this time, the silane-based gas is supplied to the wafer 200 from the lateral side of the wafer 200 (silane-based gas supply). At this time, the valves 243f to 243j may be opened to supply the inert gas into the process chamber 201 via the nozzles 249a to 249e respectively.

By supplying the silane-based gas to the wafer 200 under a processing condition described later, Si contained in the silane-based gas may be adsorbed on the surface of the wafer 200 to form seeds (nuclei). Under a processing condition described below, a crystal structure of the nucleus formed on the surface of the wafer 200 varies depending on a surface condition in which the nuclei are formed. For example, a crystal structure of the seed formed at the bottom of the recess contains at least one selected from the group of a monocrystalline crystal structure, a polycrystalline crystal structure, and an amorphous crystal structure, and the crystal structure of the seed formed on the insulating film 200a is amorphous.

A processing condition in this step is exemplified as follows:
Supply flow rate of silane-based gas supply flow rate: 0.05 to 1 slm
Supply time of each gas: 0.5 to 10 minutes Other processing conditions may be the same as those in the halosilane-based gas supply step.

After the seeds are formed on the surface of the wafer 200, the valve 243e is closed to stop the supply of the silane-based gas into the process chamber 201. Then, the gas and the like remaining in the process chamber 201 are removed from the process chamber 201 by the same processing procedure and processing condition as in the purge step of the halosilane-based gas supply step.

As the silane-based gas, it may be possible to use, for example, a silicon hydride gas such as a monosilane (SiH₄, abbreviation: MS) gas, a disilane (Si₂H₆, abbreviation: DS) gas, a trisilane (Si₃H₈) gas, a tetrasilane (Si₄H₁₀) gas, a pentasilane (Si₅H₁₂) gas, a hexasilane (Si₆H₁₄) gas, or the like. One or more of these gases may be used as the silane-based gas.

### [Performing a Predetermined Number of Times]

A cycle of alternately performing the above-described halosilane-based gas supply step and silane-based gas supply step non-simultaneously, i.e., without synchronization is performed for a predetermined number of times (n times, where n is an integer of 1 or 2 or more), whereby a seed layer 301 in which the above-described seeds are formed at high density may be formed on the surface of the wafer 200. In particular, by performing the above-described cycle multiple times, the seed layer 301 may be uniformly formed on the surface of the recess (see FIG. 5A). Under the above-described processing condition, the crystal structure of the seed layer 301 formed on the bottom of the recess is monocrystalline or amorphous, and the crystal structure of the seed layer 301 formed on the insulating film 200a is amorphous. The surface of the recess means either or both of the surface of the insulating film 200a and the bottom of the recess.

### (Film Formation Step)

Thereafter, a first gas containing a Group 14 element and a second gas containing a Group 15 or 13 element are supplied to the wafer 200 in the process chamber 201.

Specifically, the valves 243a and 243b are opened to allow the first gas and the second gas to flow through the gas supply pipes 232a and 232b, respectively. Flow rates of the first gas and the second gas are regulated by the MFCs 241a and 241b, respectively. The first gas and the second gas are supplied into the process chamber 201 via the nozzles 249a and 249b, mixed in the process chamber 201, and exhausted from the exhaust port 231a. At this time, the first gas and the second gas are supplied to the wafer 200 from the lateral side of the wafer 200 (first gas+second gas supply). At this time, the valves 243f to 243j may be opened to supply the inert gas into the process chamber 201 via the nozzles 249a to 249e, respectively.

By supplying the first gas containing, for example, Si as a Group 14 element and the second gas containing, for example, phosphorus (P) as a Group 15 element to the wafer 200 under a processing condition described later, at least the first gas may be decomposed in a gas phase, and Si may be adsorbed (deposited) on the surface of the wafer 200, i.e., on the seed layer 301 formed on the wafer 200, thereby forming a first film 302 as a Si film added (doped) with P. Under a processing condition described later, the crystal structure of the first film 302 formed on the wafer 200 becomes, for example, amorphous.

A processing conditions in this step is exemplified as follows:
Processing temperature: 300 to 500 degrees C., preferably 350 to 450 degrees C.
Processing pressure: 100 to 800 Pa, specifically 400 to 700 Pa
Supply flow rate of first gas supply: 0.5 to 1 slm
Supply flow rate of second gas: 0.001 to 2 slm
Supply flow rate of inert gas (for each gas supply pipe): 0 to 20 slm
Supply time of each gas: 1 to 300 minutes

A concentration of the second gas in the process chamber 201 in this step is a first concentration. In the present disclosure, the concentration of the second gas refers to, for example, a volume (cm³) of the second gas under a room temperature and an atmospheric pressure with respect to a volume (cm³) of the process chamber 201.

As described above, the processing temperature in this step may be higher than that in the pre-film formation seed layer formation step.

After a predetermined period of time elapses, the valves 243a and 243b are closed to stop the supply of the first gas and the supply of the second gas into the process chamber 201, respectively. Thus, film formation may be stopped before the recess formed on the wafer 200 is filled up with the first film 302. By stopping the film formation before the recess is filled up with the first film 302, a gap such as a void or a seam is generated in the recess (see FIG. 5B). Then, gaseous substances and the like remaining in the process chamber 201 are removed from the process chamber 201 by the same processing procedure and processing condition as the purging in the pre-film formation seed layer formation step (purging).

As the first gas, it may be possible to use, for example, a silicon hydride gas containing Si as a Group 14 element, such as a monosilane (SiH₄, abbreviation: MS) gas, a disilane (Si₂H₆, abbreviation: DS) gas, a trisilane (Si₃H₈) gas, a tetrasilane (Si₄H₁₀) gas, a pentasilane (Si₅H₁₂) gas, a hexasilane (Si₆H₁₄) gas, or the like. As the first gas, it may be possible to use, for example, a germanium hydride gas containing Ge (germanium) as a Group 14 element, such as a germane (GeH₄) gas, a digermane (Ge₂H₆) gas, a trigermane (Ge₃H₈) gas, a tetragermane (Ge₄H₁₀) gas, a pentagermane (Ge₅H₁₂) gas, a hexagermane (Ge₆H₁₄) gas, or the like. One or more selected from the group of these gases may be used as the first gas. As the first gas, among the above-described gases, for example, any one selected from the group of the MS gas, the DS gas, the trisilane gas, the germane gas, the digermane gas, or the trigermane gas may be used. Since these gases react (decompose) relatively easily, it is possible to improve a deposition rate. A film containing both Si and Ge may also be used as the first film 302.

As the second gas, it may be possible to use, for example, a phosphine-based gas containing P as a Group 15 element, such as a phosphine (PH₃) gas, a diphosphine (P₂H₆) gas or the like, and a halogenated phosphorous gas containing P as a Group 15 element, such as a phosphorus trichloride (PCl₃) gas or the like. As the second gas, it may be possible to use a gas containing any one selected from the group of boron (B), aluminum (Al), gallium (Ga), and indium (In) as a Group 13 element, for example, a borane-based gas (also called a borohydride-based gas) such as a monoborane (BH₃) gas, a diborane (B₂H₆) gas, a triborane (B₃H₈) gas or the like, a boron halide gas such as a trichloroborane (BCl₃) gas or the like, and a halide such as an aluminum chloride (AlCl₃) gas, a gallium chloride (GaCl₃) gas, an indium chloride (InCl₃) gas or the like. One or more selected from the group of these gases may be used as the second gas. This point also applies to a temperature-raising step and a heat treatment step, which will be described later.

### (Heat Treatment Step)

Thereafter, the wafer 200 is heat-treated to move (migrate) the Group 14 element, for example, Si contained in the first film 302. Thus, the recess is filled with the first film 302, which makes it possible to eliminate a void or seam generated in the film formation step. At this time, the pressure in the process chamber 201 may be reduced or a H-containing gas may be supplied into the process chamber 201 to promote the Si migration.

However, when the wafer 200 is heat-treated, for example, P doped into the first film 302 in the film formation step may diffuse outward from the first film 302. In particular, when the pressure inside the process chamber 201 is reduced or the H-containing gas is supplied into the process chamber 201 to promote the Si migration, the outward diffusion of P becomes remarkable.

Therefore, in the heat treatment step, for example, the second gas containing P as the Group 15 element is supplied. This makes it possible to dope P into the first film 302 and compensate for P diffused outward from the first film 302.

A processing procedure and a processing condition of the heat treatment step will be described below.

The second gas and the H-containing gas are supplied to the wafer 200, and the wafer 200 is heated (heat-treated).

Specifically, the valves 243b and 243c are opened to allow the second gas and the H-containing gas to flow through the gas supply pipes 232b and 232c. Flow rates of the second gas and the H-containing gas are regulated by the MFCs 241b and 241c, respectively. The second gas and the H-containing gas are supplied into the process chamber 201 via the nozzles 249b and 249c, mixed in the process chamber 201, and exhausted from the exhaust port 231a. At this time, the second gas and the H-containing gas are supplied to the wafer 200 from the lateral side of the wafer 200 (second gas+H-containing gas supply). At this time, the valves 243f to 243j may be opened to supply the inert gas into the process chamber 201 via the nozzles 249a to 249e.

A processing condition in this step is exemplified as follows:
Processing temperature: 400 to 700 degrees C., specifically 450 to 600 degrees C.
Processing pressure: 30 to 200 Pa, specifically 50 to 150 Pa
Supply flow rate of second gas: 0.3 to 0.8 slm
Supply flow rate of H-containing gas: 0.001 to 2 slm
Supply flow rate of inert gas (for each gas supply pipe): 0 to 20 slm
Supply time of each gas: 1 to 120 seconds, specifically 1 to 60 seconds

By heat-treating the wafer 200 under the above-described processing condition, it is possible to allow, for example, Si contained in the first film 302 to migrate. For example, the Si migration occurs in a direction in which a film thickness of the first film 302 is made uniform. In the embodiments of the present disclosure, as shown in FIG. 5B, the first film 302 is formed on the surface of the recess. Therefore, Si moves from an upper side toward a bottom side of the recess (see the arrow in FIG. 5C). In this way, the recess may be filled with the first film 302 to eliminate a void or a seam (see FIG. 5D).

The concentration of the second gas in the process chamber 201 in this step is a second concentration. The second concentration is a concentration different from the first concentration, and may be lower than the first concentration.

As described above, the pressure in the process chamber 201 in this step may be lower than that in the process chamber 201 in the film formation step.

After filling the recess with the first film 302, the valves 243b and 243c are closed to stop the supply of the second gas and the H-containing gas into the process chamber 201. Then, gaseous substances and the like remaining in the process chamber 201 are removed from the process chamber 201 by the same processing procedure and processing condition as in the purging in the pre-film formation seed layer formation step (purging).

As the H-containing gas, it may be possible to use, for example, a gas containing H. Specifically, a H₂ gas, a deuterium (D₂) gas, an activated H gas, or the like may be used. One or more selected from the group of these gases may be used as the H-containing gas.

### (After-Purge and Returning to Atmospheric Pressure)

After the heat treatment step is completed, an inert gas as a purge gas is supplied into the process chamber 201 from each of the nozzles 249a to 249e and exhausted from the exhaust port 231a. As a result, the inside of the process chamber 201 is purged such that gases remaining in the process chamber 201, reaction by-products, and the like are removed from the inside of the process chamber 201 (after-purge). Thereafter, the atmosphere in the process chamber 201 is replaced with an inert gas (inert gas replacement), and the pressure in the process chamber 201 is returned to the atmospheric pressure (returning to atmospheric pressure).

### (Boat Unloading and Wafer Discharging)

Thereafter, the seal cap 219 is lowered by the boat elevator 115 to open the lower end of the manifold 209. Then, the processed wafers 200 supported by the boat 217 are unloaded from the lower end of the manifold 209 to the outside of the reaction tube 203 (boat unloading). After the boat is unloaded, the shutter 219s is moved and the lower end opening of the manifold 209 is sealed by the shutter 219s via the O-ring 220c (shutter closing). The processed wafers 200 are discharged out of the boat 217 after being unloaded from the reaction tube 203 (wafer discharging).

### (3) Effects of the Embodiments of the Present Disclosure

According to the embodiments of the present disclosure, one or more selected from the group of the following effects may be obtained.

(a) By setting the concentration of the second gas in the film formation step to the first concentration, setting the concentration of the second gas in the heat treatment step to the second concentration, and making the first and second concentrations different from each other, it is possible to regulate the amount of P doped into the first film 302.

By supplying the second gas in the heat treatment step and doping the first film 302 with, for example, P as described above, it is possible to compensate for, for example, P that diffuses outward from the first film 302 in the heat treatment step. At this time, by making the first and second concentrations different from each other, it is possible to regulate the amount of P doped into the first film 302. Accordingly, it is possible to improve the quality of the first film 302.

(b) By setting the concentration of the second gas (second concentration) in the heat treatment step to be lower than the concentration of the second gas (first concentration) in the film formation step, in the heat treatment step, the amount of, for example, P diffused outward from the first film 302 and the amount of, for example, P doped into the first film 302 and diffused from the outside into the first film 302 may be brought close to each other.

As described above, when the wafer 200 is heat-treated, for example, P doped into the first film 302 in the film formation step may diffuse outward from the first film 302. At this time, particularly, the diffusion of, for example, P existing near the surface of the first film 302 to the outside of the first film 302 is promoted. Therefore, the P concentration in the first film 302 may become uneven.

By making the second concentration lower than the first concentration, the amount of P diffused outward from the first film 302 and the amount of P doped into the first film 302 and diffused from the outside into the first film 302 may be brought close to each other in the heat treatment step. Thus, the doping amount of P from the lower side of the first film 302 to the surface side of the first film 302, i.e., the P concentration in the first film 302 may be made uniform. As a result, the quality of the first film 302 may be reliably improved.

(c) By supplying the H-containing gas to the wafer 200 and allowing H to be adsorbed on the surface of the first film 302 in the heat treatment step, it is possible to promote migration of, for example, Si contained in the first film 302. Thus, it is possible to promote the filling of the recess with the first film 302 and to easily eliminate a void or a seam. This makes it possible to improve a filling characteristic of the first film 302 in the recess.

(d) By making the pressure inside the process chamber 201 in the heat treatment step lower than the pressure inside the process chamber 201 in the film formation step, for example, Si contained in the first film 302 is physically pulled in the heat treatment step, which makes it possible to promote the migration of Si. Thus, it is possible to promote the filling of the recess with the first film 302 and to easily eliminate a void or a seam. This makes it possible to improve the filling characteristic of the first film 302 in the recess.

(e) By supplying the inert gas to the wafer 200 in the process chamber 201 in the heat treatment step, it is possible to prevent, for example, P doped in the first film 302 from diffusing outward from the first film 302. Specifically, by setting the pressure inside the process chamber 201 to the atmospheric pressure without performing pressure reduction, it is possible to suppress, for example, P doped in the first film 302 from diffusing outward from the first film 302.

(f) By performing the pre-film formation seed layer formation step to form the seed layer 301 on the surface of the recess before performing the film formation step, it is possible to form the first film 302 with a uniform thickness throughout the inside of the recess, i.e., the first film 302 with a high step coverage. Further, by making the processing temperature in the film formation step higher than the processing temperature in the pre-film formation seed layer formation step, it is possible to form the first film 302 with a high step coverage.

(g) By performing the silane-based gas supply step under the temperature condition described above, it is possible to suppress a thermal decomposition of the silane-based gas, enhance controllability of the thickness of the seed layer 301 formed on the wafer 200, and make the thickness of the seed layer 301 smaller than a thickness of one atomic layer.

The above-described effects may also be obtained even when a predetermined substance (gaseous substance or liquid substance) is used by arbitrarily selecting the predetermined substance from the above-described various first gases, various second gases, various fourth gases, and various inert gases.

### Second Embodiment of the Present Disclosure

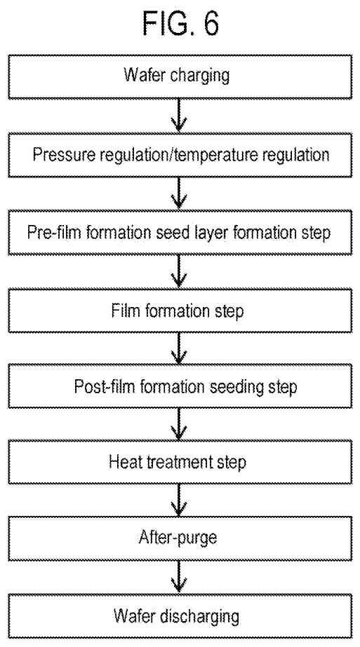

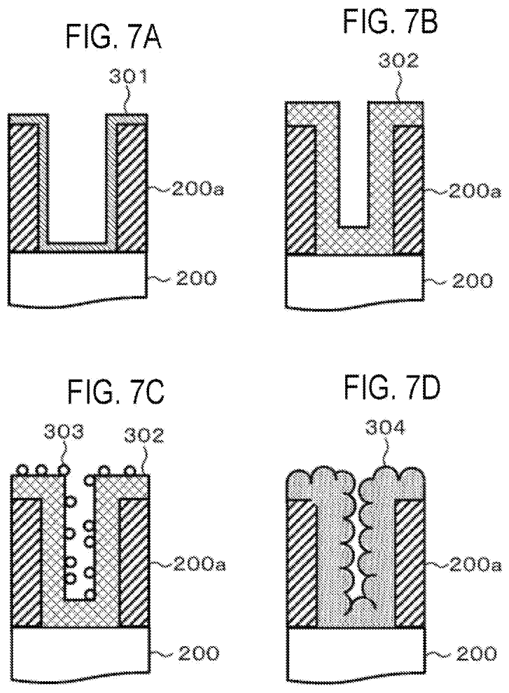

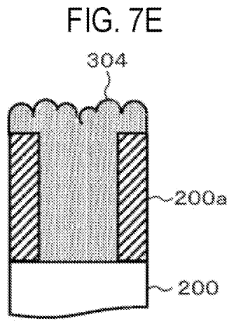

As a process of manufacturing a semiconductor device according to a second embodiment of the present disclosure, an example of a processing sequence of forming a film on a wafer 200 as a substrate will be described below mainly with reference to FIGS. 6 and 7A to 7E. The drawings used in the following description are schematic, and dimensional relationships of the respective components, ratios of the respective components, and the like shown in the drawings may not match actual ones. Moreover, dimensional relationships of the respective components, ratios of the respective components, and the like may not match one another among a plurality of drawings. In the following description, the operation of each component of the substrate processing apparatus is controlled by the controller 121.

For example, as shown in FIG. 7A, a recess is formed on the surface of the wafer 200. In the embodiments of the present disclosure, as an example, like the above-described embodiments, the bottom of the recess is made of, for example, monocrystalline Si, and the sides and the top of the recess are made of an insulating film 200a such as a SiN film or the like. The monocrystalline Si and the insulating film 200a are exposed on the surface of the wafer 200.

A processing sequence according to the embodiments of the present disclosure includes:
(A) a step of supplying a first gas containing a Group 14 element to a wafer 200 including a recess;
(B) a step of supplying a second gas containing a Group 15 or Group 13 element to the wafer 200;
(C) a step of forming a first film 302 containing a Group 14 element in the recess by performing (A) and (B), and stopping film formation before the recess is filled up with the first film 302 (film formation step);
(D) a step of supplying a third gas containing a Group 14 element to the wafer 200 after (C) and forming a second film 303 containing a Group 14 element in the recess (post-film formation seeding step); and
(E) a step of heat-treating the wafer 200 after (D) (heat treatment step).

In the following, as an example, a case where the first gas and the second gas are simultaneously supplied in the film formation step will be described.

In the present disclosure, the above-described processing sequence may be denoted as follows for the sake of convenience. The same notation may be used in the following description of modifications, other embodiments, and the like.

first gas+second gas→third gas→heat treatment

In addition, as shown in FIG. 6, the processing sequence according to the embodiments of the present disclosure may further include a pre-film formation seed layer formation step of forming a seed layer 301 on the wafer 200 by supplying a fourth gas containing a Group 14 element to the wafer 200 before performing the film formation step.

In the present disclosure, the above-described processing sequence may be denoted as follows for the sake of convenience. The same notation may be used in the following description of modifications, other embodiments, and the like.

fourth gas first gas+second gas→third gas→heat treatment

In the embodiments of the present disclosure, an example in which the pre-film formation seed layer formation step, the film formation step, the post-film formation seeding step, and the heat treatment step are performed in the named order will be described. The first gas, the second gas, the fourth gas, and the inert gas used in the embodiments of the present disclosure may be the same as the first gas, the second gas, the fourth gas, and the inert gas used in the above-described embodiments.

Processing procedures for wafer charging, boat loading, pressure regulation, temperature regulation, after-purge, and returning to atmospheric pressure in the embodiments of the present disclosure may be the same as those in the above-described embodiments. In addition, processing procedures and processing conditions in the pre-film formation seed layer formation step and the film formation step of the embodiments of the present disclosure may be the same as those in the pre-film formation seed layer formation step and the film formation step of the above-described embodiments.

However, a concentration of the second gas in the film formation step of the embodiments of the present disclosure is not particularly limited to the first concentration exemplified as the concentration of the second gas in the film formation step of the above-described embodiments.

In the embodiments of the present disclosure, the seed layer 301 is formed on the surface of the recess by performing the pre-film formation seed layer formation step (see FIG. 7A), and then the first film 302 is formed on the surface of the recess by continuing the film formation step (see FIG. 7B). In the film formation step, by stopping the film formation before the recess is filled up with the first film 302 as in the above-described embodiments, a gap such as a void or a seam is generated in the recess.

The processing procedures and processing conditions in the post-film formation seeding step and the heat treatment step will be described below.

### (Post-Film Formation Seeding Step)

In this step, the third gas containing a Group 14 element and the second gas are supplied to the wafer 200 in the process chamber 201.

Specifically, the valves 243a and 243b are opened to allow the third gas and the second gas to flow through the gas supply pipes 232a and 232b, respectively. Flow rates of the third gas and the second gas are regulated by the MFCs 241a and 241b, respectively. The third gas and the second gas are supplied into the process chamber 201 via the nozzles 249a and 249b, mixed in the process chamber 201, and exhausted from the exhaust port 231a. At this time, the third gas and the second gas are supplied to the wafer 200 from the lateral side of the wafer 200 (third gas+second gas supply). At this time, the valves 243f to 243j may be opened to supply the inert gas into the process chamber 201 via the nozzles 249a to 249e respectively.

A processing condition in this step is exemplified as follows:
Processing temperature: 350 to 700 degrees C., specifically 400 to 650 degrees C.
Processing pressure: 400 to 1000 Pa
Supply flow rate of third gas: 0.1 to 1 slm
Supply flow rate of second gas: 0.001 to 2 slm
Supply flow rate of inert gas (for each gas supply pipe): 0 to 20 slm
Supply time of each gas: 1 to 100 minutes.

By supplying, for example, a third gas containing Si as a Group 14 element to the wafer 200 under the above-described processing conditions, Si contained in the third gas may be adsorbed on the first film 302, and seeds (nuclei) as a second film 303 may be formed. As shown in FIG. 7C, the second film 303 is formed on the first film 302 in the recess discontinuously, for example, in the form of crystal nuclei. Under the processing conditions described above, the crystal structure of the formed second film 303 contains at least one selected from the group of a monocrystalline crystal structure or a polycrystalline crystal structure. The discontinuous film is also called an island-like film, a film in which crystal nuclei are sparsely formed, or a granular film.

Under the above-described processing conditions, for example, by controlling at least one selected from the group of the flow rate of the third gas, the supply time of the third gas, and the processing pressure, it is possible to control, for example, the grain size and density of the second film 303 in the form of crystal nuclei. For example, by increasing at least one selected from the group of the supply flow rate of the third gas, the supply time of the third gas, and the processing pressure, it is possible to increase the grain size of the second film 303 on the first film 302 or to increase the density of the second film 303.

As described above, the processing temperature in this step may be higher than the processing temperature in the pre-film formation seed layer formation step and the film formation step.

After forming the second film 303 on the first film 302, the valves 243a and 243b are closed to stop the supply of the third gas and the supply of the second gas into the process chamber 201. Then, gaseous substances and the like remaining in the process chamber 201 are removed from the process chamber 201 by the same processing procedure and processing condition as in the purging in the pre-film formation seed layer formation step of the above-described embodiments (purging).

As the third gas, it may be possible to use, for example, a hydrogen compound containing Si or Ge as a Group 14 element, such as a DCS gas, a MS gas, a DS gas, a trisilane gas, a tetrasilane gas, a pentasilane gas, a hexasilane gas, a germane gas, a digermane gas, a trigermane gas, a tetrasilane gas, a pentagermane gas, a hexagermane gas or the like. One or more selected from the group of these gases may be used as the third gas. Since these gases are decomposed relatively easily, it is possible to form crystal-nucleus-like seeds. Among these gases, a halogen-free gas, i.e., a gas other than the DCS gas may be used. These gases are more easily decomposed and may reliably form the crystal-nucleus-like seeds. Further, as the third gas, a gas (compound) different from the above-described fourth gas may be used. The pre-film formation seed layer formation step and the post-film formation seeding step are common in that seeds are formed on the wafer 200. However, the films to be formed are different in that a discontinuous film is formed in the post-film formation seeding step whereas a continuous film (uniform film) is formed in the pre-film formation seed layer formation step. By using different gases, it is possible to facilitate the formation of these different films.

### (Heat Treatment Step)

Thereafter, the wafer 200 is heated (heat-treated).

A processing condition in this step is exemplified as follows:
Processing temperature: 400 to 750 degrees C., specifically 450 to 700 degrees C.
Processing pressure: 30 to 200 Pa, specifically 50 to 150 Pa
Supply flow rate of inert gas (for each gas supply pipe): 0 to 20 slm
Supply time of inert gas: 1 to 120 seconds, specifically 1 to 60 seconds

By heat-treating the wafer 200 under the processing conditions described above, the first film 302 may be crystallized, and the grain size of the second film 303 may be increased accordingly. In the embodiments of the present disclosure, for the sake of convenience, the crystallized first film 302 and the second film 303 with an increased grain size as a result of the crystallization of the first film 302 are collectively referred to as a third film 304 (see FIG. 7D). By performing this step, the recess may be filled with the third film 304 to eliminate a void or a seam (see FIG. 7E).

After filling the recess with the third film 304, the output of the heater 207 is stopped. Then, gaseous substances and the like remaining in the process chamber 201 are removed from the process chamber 201 by the same processing procedure and processing condition as in the purging in the pre-film formation seed layer formation step of the above-described embodiments (purging).

According to the embodiments of the present disclosure, one or more selected from the group of the following effects may be obtained, in addition to at least some selected from the group of the effects described in the above-described embodiments.

By supplying, for example, a third gas containing Si as a group 14 element to the wafer 200 in the post-film formation seeding step, Si contained in the third gas may be adsorbed on the first film 302, and seeds (the second film 303) may be formed on the first film 302 in the recess. Furthermore, by heating the wafer 200 in the heat treatment step, the first film 302 may be crystallized, and the grain size of the second film 303 may be increased accordingly. This makes it possible to fill the recess with the third film 304 and eliminate a void or seam. In this way, the filling characteristics of the third film 304 in the recess may be improved, and the quality of the third film 304 may be improved.

By forming the second film 303 on the first film 302 discontinuously, for example, in the form of crystal nuclei in the post-film formation seeding step, it is possible to control surface roughness of the first film 302. Specifically, for example, by regulating the supply flow rate of the third gas and controlling the grain size and the density of the second film 303 in the post-film formation seeding step, it is possible to control the surface roughness of the first film 302. By regulating the surface roughness of the first film 302 in the post-film formation seeding step in this way, it is possible to control a filling amount (state) of the third film 304 in the recess in the heat treatment step.

By setting the processing temperature in the post-film formation seeding step higher than the processing temperature in the pre-film formation seed layer formation step and the film formation step, it is possible to control the surface state (surface roughness) of the third film 304 and the filling amount in the recess in the heat treatment step.

By supplying the second gas to the wafer 200 in the post-film formation seeding step, it is possible to suppress, for example, the outward diffusion of P from the first film 302, which occurs in the post-film formation seeding step.

The heat treatment step in the embodiments of the present disclosure may not be performed. That is, the substrate processing in the substrate processing apparatus may be completed by performing the post-film formation seeding step. The heat treatment step may be performed in another substrate processing apparatus. By completing the substrate processing at the post-film formation seeding step and not performing the heat treatment step, it is possible to save a temperature regulation time in the substrate processing apparatus configured to perform the substrate processing up to the post-film formation seeding step. The temperature regulation time refers to a time relating to raising the temperature to a temperature at which the heat treatment step is performed and a time relating to lowering the temperature after the heat treatment step. By saving the temperature regulation time, it is possible to shorten a substrate processing time in the substrate processing apparatus. That is, it is possible to improve a substrate processing throughput. On the other hand, when the post-film formation seeding step and the heat treatment step are performed in the same substrate processing apparatus, it is possible to suppress surface changes such as native oxidation of the film existing on the wafer 200, and the like.

### Other Embodiments of the Present Disclosure

The embodiments of the present disclosure are specifically described above. However, the present disclosure is not limited to the above-described embodiments, and various modifications may be made without departing from the scope of the present disclosure.

In the above-described embodiments of the present disclosure, the case where in the pre-film formation seed layer formation step, one of the two kinds of fourth gases is the halosilane-based gas and the other is the silane-based gas, is described by way of example. However, the present disclosure is not limited thereto. In the present disclosure, for example, both of the two kinds of fourth gases may be the halosilane-based gas. Even in such a case, at least some selected from the group of the effects described in the above-described embodiments may be obtained. However, in this case, different halosilane-based gases may be used.

In the second embodiment described above, the case where the second gas is not supplied to the wafer 200 in the heat treatment step is described by way of example. However, the present disclosure is not limited thereto. In the present disclosure, for example, in the heat treatment step of the second embodiment described above, for example, a second gas containing P as a Group 15 element may be supplied. Also in such a case, the same effects as those of the above-described second embodiment may be obtained. In the embodiments of the present disclosure, by supplying the second gas in the heat treatment step and doping the first film 302 with P, it is possible to compensate for, for example, P that diffuses outward from the first film 302 in the heat treatment step.

However, in the heat treatment step of the second embodiment described above, the concentration of the second gas when supplying the second gas is not limited to the second concentration exemplified as the concentration of the second gas in the heat treatment step of the first embodiment described above. Further, in the second embodiment described above, the concentration of the second gas in the film formation step and the concentration of the second gas in the heat treatment step may be the same concentration or may be different concentrations. In the second embodiment described above, the concentration of the second gas in the film formation step may be lower than or higher than the concentration of the second gas in the heat treatment step. Also in these cases, at least some selected from the group of the effects described in the above-described embodiments may be obtained.

Although not specifically described in the above-described embodiments, a temperature-raising step of raising the temperature inside the process chamber 201 may be performed before performing the heat treatment step. At this time, for example, a second gas containing P as a Group 15 element may be supplied. Also in such a case, the same effects as those of the above-described embodiments may be obtained. In the embodiments of the present disclosure, it is also possible to suppress, for example, the outward diffusion of P from the first film 302 caused by performing the temperature-raising step.

In the above-described embodiments, the gas containing Si is mainly described as the gas containing the Group 14 element. However, the present disclosure is not limited thereto. For example, the present disclosure may use a gas containing Ge as the gas containing the Group 14. Further, in the above-described embodiments, the gas containing P, which is a Group 15 element, is mainly described as the second gas containing the Group 15 or Group 13 element. However, the present disclosure is not limited thereto. For example, the present disclosure may use a gas containing any one of B, Al, Ga, and In as the gas containing the Group 13 element. Also in these cases, the same effects as those of the above-described embodiments may be obtained.

In the above-described embodiments, the example of forming the Si-based film on the wafer 200 is described. However, the present disclosure is not limited thereto. For example, the present disclosure may also be applied to formation of films containing Group 14 elements. The films containing Group 14 elements include, for example, a film containing at least one selected from the group of Si, Ge, and SiGe as a main component.

The recipe used for each process may be provided separately according to the processing contents, and recorded and stored in the memory 121c via an electric communication line or an external memory 123. When starting each process, the CPU 121a properly may select an appropriate recipe from a plurality of recipes recorded and stored in the memory 121c according to the process contents. This makes it possible to form films of various film types, composition ratios, film qualities, and film thicknesses in one substrate processing apparatus with high reproducibility. In addition, burden on an operator may be reduced, and each process may be quickly started while avoiding operation errors.

The above-described recipes are not limited to the newly provided ones, but may be provided by, for example, changing the existing recipes already installed in the substrate processing apparatus. In the case of changing the recipes, the changed recipes may be installed in the substrate processing apparatus via an electric communication line or a recording medium in which the recipes are recorded. In addition, the input/output device 122 included in the existing substrate processing apparatus may be operated to directly change the existing recipes already installed in the substrate processing apparatus.

In the above-described embodiments, the example is described in which the film is formed by using a batch-type substrate processing apparatus configured to process a plurality of substrates at a time. The present disclosure is not limited to the above-described embodiments, but may be suitably applied to, for example, a case where a film is formed by using a single-substrate-type substrate processing apparatus configured to process one or several substrates at a time. Furthermore, in the above-described embodiments, the example is described in which the film is formed by using the substrate processing apparatus including a hot-wall-type process furnace. The present disclosure is not limited to the above-described embodiments but may also be suitably applied to a case where a film is formed by using a substrate processing apparatus including a cold-wall-type process furnace.

Even when these substrate processing apparatuses are used, each process may be performed under the same processing procedure and processing condition as those of the above-described embodiments and modifications. The same effects as those of the above-described embodiments and modifications may be obtained.

In addition, the above-described embodiments and modifications may be used in combination as appropriate. Processing procedures and processing conditions at this time may be, for example, the same as the processing procedures and processing conditions of the above-described embodiments and modifications.

According to the present disclosure in some embodiments, it is possible to improve a quality of a film formed on a substrate.

While certain embodiments are described above, these embodiments are presented by way of example, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate, comprising:
(a) supplying a first gas containing a Group 14 element to the substrate including a recess;
(b) supplying a second gas containing a Group 15 or Group 13 element to the substrate;
(c) forming a first film containing the Group 14 element in the recess by performing (a) and (b) with the second gas at a first concentration, and stopping film formation before the recess is filled up with the first film; and
(d) after (c), performing (b) with the second gas at a second concentration and heat-treating the substrate.

2. The method of claim 1, wherein the first concentration and the second concentration are different from each other.

3. The method of claim 1, wherein the second concentration is lower than the first concentration.

4. The method of claim 1, wherein in (d), a hydrogen-containing gas is supplied to the substrate.

5. The method of claim 3, wherein in (d), a hydrogen-containing gas is supplied to the substrate.

6. The method of claim 4, wherein in (d), a pressure in a space in which the substrate is present is lower than a pressure in the space in (c).

7. The method of claim 5, wherein in (d), a pressure in a space in which the substrate is present is lower than a pressure in the space in (c).

8. The method of claim 1, wherein in (d), an inert gas is supplied to the substrate.

9. The method of claim 1, further comprising:
(e) after (c), supplying a third gas containing the Group 14 element to the substrate to form a second film containing the Group 14 element in the recess.

10. The method of claim 9, wherein the third gas supplied in (e) is a hydrogen compound.

11. The method of claim 10, wherein the hydrogen compound does not contain halogen.

12. The method of claim 9, wherein in (e), the second gas is supplied.

13. The method of claim 9, wherein the second film formed in (e) is formed discontinuously.

14. The method of claim 9, further comprising:
(f) before (c), supplying a fourth gas containing the Group 14 element to the substrate to form a seed layer containing the Group 14 element in the recess.

15. The method of claim 14, wherein a temperature of the substrate in (f) is lower than a temperature of the substrate in (e).

16. The method of claim 15, wherein the fourth gas used in (f) and the third gas used in (e) are different compounds.

17. The method of claim 16, wherein in (0, a halogen-containing gas is used as the fourth gas, and
wherein in (e), a halogen-free gas is used as the third gas.

18. A method of manufacturing a semiconductor device, comprising the method of claim 1.

19. A non-transitory computer-readable recording medium storing a program that causes, by a computer, a substrate processing apparatus to perform:
(a) supplying a first gas containing a Group 14 element to a substrate including a recess;
(b) supplying a second gas containing a Group 15 or Group 13 element to the substrate;
(c) forming a first film containing the Group 14 element in the recess by performing (a) and (b) with the second gas at a first concentration, and stopping film formation before the recess is filled up with the first film; and
(d) after (c), performing (b) with the second gas at a second concentration and heat-treating the substrate.

20. A substrate processing apparatus, comprising:
a first gas supply system configured to supply a first gas containing a Group 14 element to a substrate including a recess;
a second gas supply system configured to supply a second gas containing a Group 15 or Group 13 element to the substrate including the recess;
a heater configured to heat the substrate; and
a controller configured to be capable of controlling the first gas supply system, the second gas supply system, and the heater so as to perform:
(a) supplying the first gas to the substrate;
(b) supplying the second gas to the substrate;
(c) forming a first film containing the Group 14 element in the recess by performing (a) and (b) with the second gas at a first concentration, and stopping film formation before the recess is filled up with the first film; and
(d) after (c), performing (b) with the second gas at a second concentration and heat-treating the substrate.
